(19) United States
(12) Patent Application Publication
(10) Pub. No.: US 2021/0219476 A1
(43) Pub. Date: Jul. 15, 2021

(54) VARIABLE PITCH ELECTRONIC COMPONENT MASS TRANSFER APPARATUS AND METHOD

(71) Applicant: GUANGDONG UNIVERSITY OF TECHNOLOGY, GUANGZHOU (CN)

(72) Inventors: Xin CHEN, GUANGZHOU (CN); Yunbo HE, GUANGZHOU (CN); Xiquan MAI, GUANGZHOU (CN); Chengqiang CUI, GUANGZHOU (CN); Qiang LIU, GUANGZHOU (CN); Jian GAO, GUANGZHOU (CN); Zhijun YANG, GUANGZHOU (CN); Xun CHEN, GUANGZHOU (CN); Yun CHEN, GUANGZHOU (CN); Kai ZHANG, GUANGZHOU (CN); Hui TANG, GUANGZHOU (CN); Yu ZHANG, GUANGZHOU (CN)

(21) Appl. No.: 17/218,367

(22) Filed: Mar. 31, 2021

Related U.S. Application Data
(63) Continuation of application No. PCT/CN2018/124561, filed on Dec. 28, 2018.

(30) Foreign Application Priority Data
Oct. 16, 2018 (CN) 201811204664.4

(51) Int. Cl. H05K 13/04; H01L 33/00; H01L 33/62

(52) U.S. Cl. CPC H05K 13/0411; H01L 33/005; H01L 2933/0066; H05K 13/0465; H01L 33/62

(57) ABSTRACT

A variable pitch electronic component mass transfer apparatus is disclosed. A die-bond transfer head is disposed below each of the die-bond brackets. The die-bond connecting rod is provided with die-bond movable nodes arranged equidistantly. Each of the die-bond movable node is hinged to one of the die-bond brackets. An output end of the die-bond linear motor drives the die-bond connecting rod to move telescopically. A flip-chip transfer head is disposed below each of the flip-chip brackets. The flip-chip connecting rod is provided with flip-chip movable nodes arranged equidistantly. Each of the flip-chip movable nodes is hinged to one of the flip-chip brackets. An output end of the flip-chip linear motor drives the flip-chip connecting rod to move telescopically. An output end of the connecting rod rotating motor is connected to the flip-chip rail, and is configured to turn over the flip-chip rail.

### CROSS-REFERENCE TO RELATED APPLICATIONS

This application is a continuation of International Patent Application No. PCT/CN2018/124561 with a filing date of Dec. 28, 2018, designating the United States, now pending, and further claims priority to Chinese Patent Application No. 201811204664.4 with a filing date of Oct. 16, 2018. The content of the aforementioned applications, including any intervening amendments thereto, are incorporated herein by reference.

### TECHNICAL FIELD

The present disclosure relates to the field of novel semiconductor displays, and more particularly, to a variable pitch electronic component mass transfer apparatus and method.

### BACKGROUND

Micro-LED is a display technology for miniaturizing and matrixing LED structures, and individually driving and addressing control for each pixel point. Since various indexes, such as brightness, lifetime, contrast, reaction time, energy consumption, visual angle and resolution, of the Micro-LED technology are superior to the LCD and OLED technology, it is considered to be a new generation of display technology capable of performing beyond the OLED and the conventional LED. However, because of the high efficiency, 99.9999% yield and the requirement of the transfer precision within plus or minus 0.5 μm in the packaging process, the size of the Micro-LED apparatus is substantially less than 50 μm and the number is several tens to several millions. Therefore, a core technical problem still needs to be overcome during the industrialization of the Micro-LED is the mass transfer technology of the Micro-LED component. Currently, the Micro-LED component transfer method mainly includes an electrostatic force adsorption method, a Van der Waals force transfer method, an electromagnetic force adsorption method, a patterned sputtered laser ablation method, a fluid assembly method, and the like. The electrostatic force adsorption method, the van der Waals force transfer method and the electromagnetic force adsorption method respectively act by electrostatic force, van der Waals force and electromagnetic force to accurately adsorb a large amount of Micro-LEDs, and then transfer them to a target substrate, and release them accurately. However, the above three methods cannot solve the problem that the distance between the Micro-LED on the wafer and the distance between the Micro-LED on the substrate are different. The patterned sputtered laser ablation method directly peels the Micro-LED from the laser on the wafer, but requires the use of expensive excimer lasers. The fluid assembly method utilizes a brush barrel to roll on the substrate, so that the Micro-LED is led to the liquid suspension, and the LED is led to a corresponding well on the substrate by fluid force. However, this method has a certain randomness and cannot ensure a self-assembled yield.

### SUMMARY

An object of the present disclosure is to propose a variable pitch electronic component mass transfer apparatus and method to solve the above problems.

For this purpose, the present disclosure adopts the following technical solutions:

A variable pitch electronic component mass transfer apparatus, including a die-bond welding arm, a die-bond driving movement platform, a flip-chip welding arm, a flip-chip driving movement platform and an operation platform.

A plurality of die-bond welding arms are provided, and each of the die-bond welding arms includes a die-bond rail, a die-bond bracket, a die-bond transfer head, a die-bond connecting rod and a die-bond linear motor. A plurality of die-bond brackets are provided, and the plurality of die-bond brackets are all slidably connected to the die-bond rail. An die-bond transfer head is disposed below each of the die-bond brackets. The die-bond connecting rod is provided with die-bond movable nodes arranged equidistantly. Each of the die-bond movable node is hinged to one of the die-bond brackets. The die-bond linear motor is disposed at one end of the die-bond rail. An output end of the die-bond linear motor drives the die-bond connecting rod to move telescopically.

The die-bond welding arm is connected to the die-bond driving movement platform, and the die-bond driving movement platform drives the die-bond welding arm to move along X, Y and Z axes.

The number of the flip-chip welding arms is the same as the number of the die-bond welding arms. Each of the flip-chip arms includes a flip-chip rotating motor, a flip-chip rail, a flip-chip bracket, a flip-chip transfer head, a flip-chip connecting rod and a flip-chip linear motor. A plurality of flip-chip brackets are provided, and the plurality of flip-chip brackets are all slidably connected to the flip-chip rail. A flip-chip transfer head is disposed below each of the flip-chip brackets. The flip-chip connecting rod is provided with flip-chip movable nodes arranged equidistantly. Each of the flip-chip movable nodes is hinged to one of the flip-chip brackets. The flip-chip linear motor is disposed at one end of the flip-chip rail. An output end of the flip-chip linear motor drives the flip-chip connecting rod to move telescopically. An output end of the connecting rod rotating motor is connected to the flip-chip rail, and is configured to turn over the flip-chip rail.

The flip-chip welding arm is connected to the flip-chip driving movement platform, the flip-chip driving movement platform drives the flip-chip welding arm to move along X, Y and Z axes, and the flip-chip driving movement platform is provided with a visual servo alignment system.

The die-bond linear motor, the die-bond driving platform, the flip-chip rotating motor, the flip-chip linear motor and the flip-chip driving platform are electrically connected to the operation platform.

The die-bond transfer heads and the flip-chip transfer heads are both bipolar transfer heads, a Micro-LED is grasped when a positive voltage is applied, and a Micro-LED is released when a negative voltage is applied. The die-bond connecting rod and the flip-chip connecting rod are both parallelogram mechanisms. The parallelogram mechanism includes a plurality of first links and a plurality of second links. The length of the first link is the same as the length of the second link. The midpoint of each of the first links and the midpoint of one of the second links are hinged to each other, forming an X-shaped module. Two adjacent X-shaped modules being hinged to each other to form the parallelogram mechanism. The two adjacent X-shaped module hinges are the active nodes. Two ends of the parallelogram mechanism are further provided with a third link and a fourth link, one end of the third link is hinged to an end of a first link located at one end of the parallelogram, and the other end of the third link is the movable node. One end of the fourth link is hinged to an end of a second link located at the other end of the parallelogram, and the other end of the fourth link is the movable node.

The operation platform includes a visualized PLC screen and an integrated PLC control system, and the integrated PLC control system is electrically connected to the die-bond linear motor, the die-bond driving movement platform, the flip-chip rotating motor, the flip-chip linear motor and the flip-chip driving movement platform, respectively.

The die-bond welding arm further includes a die-bond limiting device, and the die-bond limiting device is disposed at one end of the die-bond rail for limiting the die-bond brackets on the die-bond rail.

The flip-chip welding arm further includes a flip-chip limiting device, and the flip-chip limiting device is arranged at one end of the flip-chip rail for limiting the flip-chip brackets on the flip-chip rail.

A transferring method using the variable pitch electronic component mass transfer apparatus includes the following steps:

Step 1: driving the Z axis of the flip-chip driving movement platform, so that the flip-chip transfer head is kept at a distance from the Micro-LED, and then driving the XY axis of flip-chip driving movement platform to perform machine vision alignment;

Step 2: driving the flip-chip linear motor according to the pitch of the substrate Micro-LED to be grabbed, changing the length of the flip-chip connecting rod, so that each flip-chip transfer head is aligned with the Micro-LED of the substrate respectively;

Step 3: applying a positive voltage to all the flip-chip transfer heads to grasp the Micro-LED of the substrate;

Step 4: driving the flip-chip rotating motor so that the flip-chip welding arm is inverted 180 degrees, and then driving the XY axis of the die-bond driving movement platform and the die-bond linear motor so that the die-bond transfer head aligns the Micro-LED on the flip-chip transfer head, and then driving the Z axis of the die-bond driving platform so as to press the die-bond transfer head on the Micro-LED; then applying a positive voltage to the die-bond transfer head to grasp the Micro-LED, and applying a negative voltage to the flip-chip transfer head to release the Micro-LED;

Step 5: driving the die-bond linear motor according to the distance required when the micro-LED is placed wherein the distance between two adjacent die-bond brackets is c1, then changing the length of the die-bond connecting rod wherein the distance between two adjacent die-bond brackets is c2 and the distance between two adjacent die-bond transfer heads is L2;

Step 6: driving the XY axis of the die-bond driving movement platform, positioning the Micro-LED grasped by the die-bond transfer head at a target position, then driving the Z axis of the die-bond driving movement platform, moving the die-bond transfer head down to a target board, and then applying a negative voltage to the die-bond transfer head, so that the die-bond transfer head releases the Micro-LED;

Step 7: returning to Step 1.

A longitudinal linear deformation coefficient of the die-bond connecting rod is c, and in the step 5, after the die-bond linear motor is driven to change the length of the die-bond connecting rod, the pitch between two adjacent die-bond transfer heads is c2=c1*c.

The pitch of the Micro-LEDs of the substrate is L1, a grabbing point is marked every a elements, and the pitch of two adjacent Micro-LEDs on the target board is L2, L2=L1*a*c.

A response time of the die-bond connecting rod and the flip-chip connecting rod is 10-100 ms.

### BRIEF DESCRIPTION OF THE DRAWINGS

The drawings further illustrate the present disclosure, but the contents of the drawings are not intended to limit the present disclosure.

FIG. 1 is a schematic diagram of a micro-LED mass transfer process according to an embodiment of the present disclosure;

FIG. 2 is a structural schematic diagram of a welding arm according to an embodiment of the present disclosure;

FIG. 3 is a schematic diagram illustrating the flipping of a flip-chip welding arm and the docking exchange of a die-bond welding arm according to an embodiment of the present disclosure;

FIG. 4 is a schematic diagram of aligning a target board with a die-bond transfer head according to an embodiment of the present disclosure;

FIG. 5 is a schematic diagram of placing a Micro-LED by a die-bond transfer head according to an embodiment of the present disclosure.

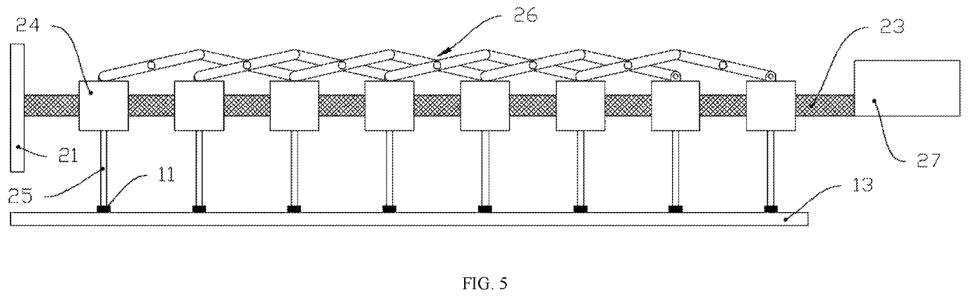

In the drawings: a Micro-LED 11, a substrate 12, a target board 13, a die-bond limiting device 21, a die-bond rail 23, a die-bond bracket 24, a die-bond transfer head 25, a die-bond connecting rod 26, a die-bond linear motor 27, a flip-chip rotating motor 31, a flip-chip limiting device 32, a flip-chip rail 33, a flip-chip connecting rod 34, a flip-chip bracket 35, a flip-chip transfer head 36, a flip-chip linear motor 37, a first link 41, a second link 42, a third link 43, and a fourth link 44.

### DETAILED DESCRIPTION OF EMBODIMENTS

The technical solutions of the present disclosure will be further described below with reference to the accompanying drawings and by way of specific embodiments.

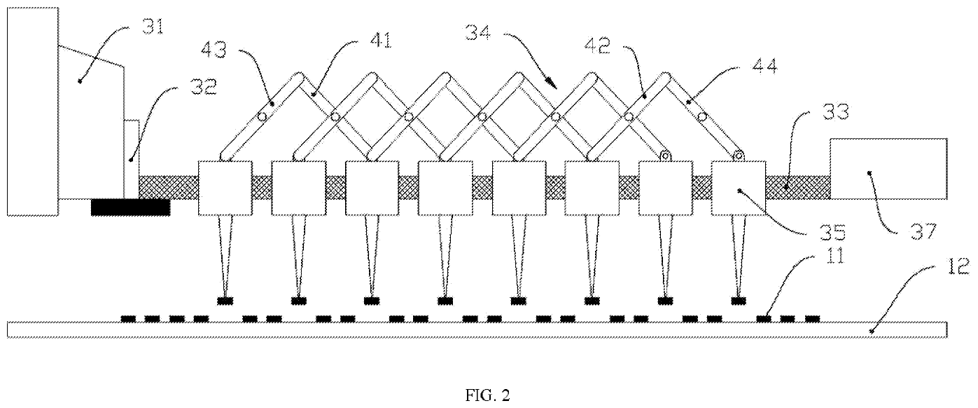

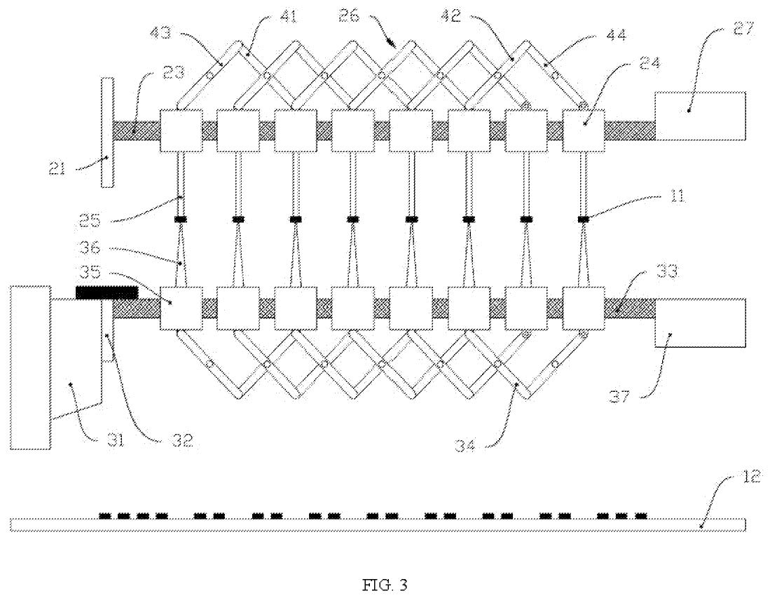

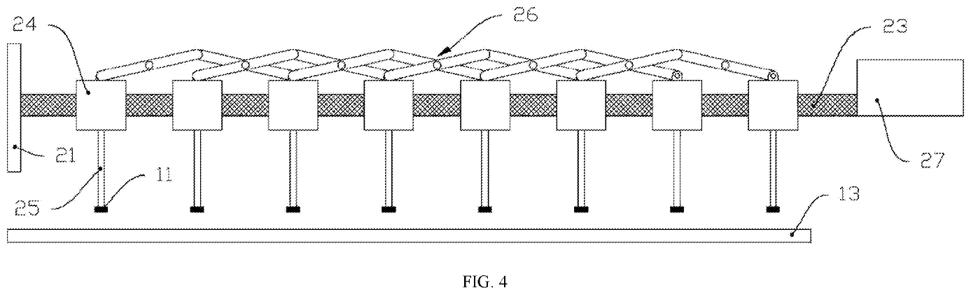

A variable pitch electronic component mass transfer apparatus of the present embodiment, as shown in FIGS. 2-4, includes a die-bond welding arm, a die-bond driving movement platform, a flip-chip welding arm, a flip-chip driving movement platform and an operation platform.

A plurality of die-bond welding arms are provided, and each of the die-bond welding arms includes a die-bond rail 23, a die-bond bracket 24, a die-bond transfer head 25, a die-bond connecting rod 26 and a die-bond linear motor 27. A plurality of die-bond brackets 24 are provided, and the plurality of die-bond brackets 24 are all slidably connected to the die-bond rail 23. An die-bond transfer head 25 is disposed below each of the die-bond brackets 24. The die-bond connecting rod 26 is provided with die-bond movable nodes arranged equidistantly. Each of the die-bond movable node is hinged to one of the die-bond brackets 24. The die-bond linear motor 27 is disposed at one end of the die-bond rail 23. An output end of the die-bond linear motor 27 drives the die-bond connecting rod 26 to move telescopically.

The die-bond welding arm is connected to the die-bond driving movement platform, and the die-bond driving movement platform drives the die-bond welding arm to move along X, Y and Z axes.

The number of the flip-chip welding arms is the same as the number of the die-bond welding arms. Each of the flip-chip arms includes a flip-chip rotating motor 31, a flip-chip rail 33, a flip-chip bracket 35, a flip-chip transfer head 36, a flip-chip connecting rod 34 and a flip-chip linear motor 37. A plurality of flip-chip brackets 35 are provided, and the plurality of flip-chip brackets 35 are all slidably connected to the flip-chip rail 33. A flip-chip transfer head 36 is disposed below each of the flip-chip brackets 35. The flip-chip connecting rod 34 is provided with flip-chip movable nodes arranged equidistantly. Each of the flip-chip movable nodes is hinged to one of the flip-chip brackets 35. The flip-chip linear motor 37 is disposed at one end of the flip-chip rail 33. An output end of the flip-chip linear motor 37 drives the flip-chip connecting rod 34 to move telescopically. An output end of the connecting rod rotating motor 31 is connected to the flip-chip rail 33, and is configured to turn over the flip-chip rail 33.

The flip-chip welding arm is connected to the flip-chip driving movement platform, the flip-chip driving movement platform drives the flip-chip welding arm to move along X, Y and Z axes, and the flip-chip driving movement platform is provided with a visual servo alignment system.

The die-bond linear motor 27, the die-bond driving platform, the flip-chip rotating motor 31, the flip-chip linear motor 37 and the flip-chip driving platform are electrically connected to the operation platform.

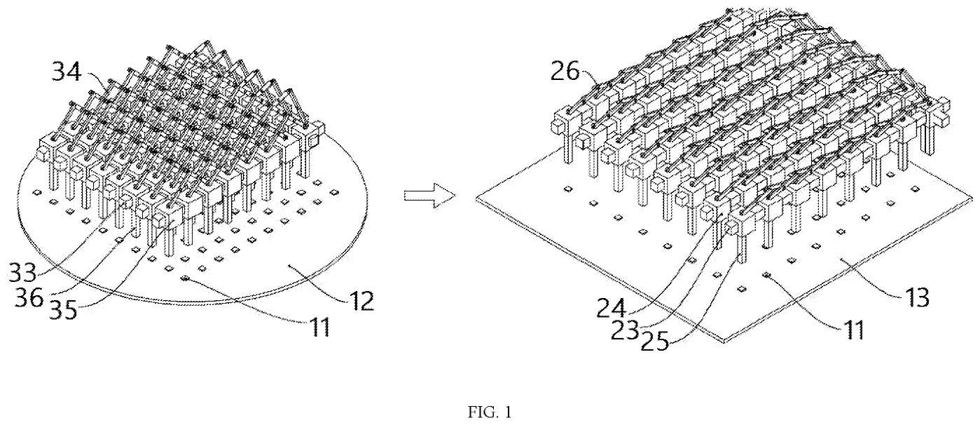

In the existing transfer method, the transfer heads in the transfer mechanism are generally connected by a rigid structure, so that the distance between the transfer heads cannot be adjusted after the transfer heads grab the Micro-LED 11 from the substrate 12, so that the distance of the transfer heads placing on the target substrate 13 cannot be controlled, so that the distance between the Micro-LED 11 in the target board 13 can only depend on the transfer head template distance. As shown in FIG. 1, in the present disclosure, two adjacent die-bond brackets 24 and flip-chip brackets 35 are connected by using a die-bond connecting rod 26 and a flip-chip connecting rod 34. Correspondingly, two adjacent die-bond welding arms and two adjacent flip-chip welding arms are also connected by using a parallelogram mechanism. The distance between two adjacent die-bond brackets 24 can be changed by changing the length of the die-bond connecting rod 26. By changing the length of the parallelogram mechanism, the distance between two adjacent die-bond welding arms and two adjacent flip-chip solder arms is changed. Thus, the Micro-LED 11 is precisely grabbed and released. The length of the flip-chip connecting rod 34 is changed according to the pitch of the Micro-LED 11 to be placed, so as to change the distance between two adjacent coating brackets 35. In this way, the Micro-LED 11 is precisely placed on the target board 13. Thus, the distance between the electronic components is completely controllable, which inventively overcomes the limitation that the Micro-LED 11 spacing of the target board 13 can only depend on the transfer head template distance. The present disclosure has great application value in the field of semiconductor manufacturing and has higher social economy benefits.

The die-bond transfer heads 25 and the flip-chip transfer heads 36 are both bipolar transfer heads, a Micro-LED 11 is grasped when a positive voltage is applied, and a Micro-LED 11 is released when a negative voltage is applied. The die-bond connecting rod 26 and the flip-chip connecting rod 34 are both parallelogram mechanisms. The parallelogram mechanism includes a plurality of first links 41 and a plurality of second links 42. The length of the first link 41 is the same as the length of the second link 42. The midpoint of each of the first links 41 and the midpoint of one of the second links 42 are hinged to each other, forming an X-shaped module. Two adjacent X-shaped modules being hinged to each other to form the parallelogram mechanism. The two adjacent X-shaped module hinges are the active nodes. Two ends of the parallelogram mechanism are further provided with a third link 43 and a fourth link 44, one end of the third link 43 is hinged to an end of a first link 41 located at one end of the parallelogram, and the other end of the third link 43 is the movable node. One end of the fourth link 44 is hinged to an end of a second link 42 located at the other end of the parallelogram, and the other end of the fourth link 44 is the movable node.

Because the parallelogram has instability, it is easy to deform. The parallelogram mechanism is adopted to connect each of the die-bond brackets 24 or the flip-chip brackets 35 to control the distance between the die-bond brackets 24 or the flip-chip brackets 35 by deformation of the parallelogram mechanism. The distance between each die-bond bracket 24 and each flip-chip bracket 35 is controllable. Even if the distance between the Micro-LED 11 on the substrate 12 and the Micro-LED 11 on the target board 13 is different, alternatively, the distance between the respective die-bond brackets 24 or the distance between the respective flip-chip brackets 35 can be changed by the die-bond connecting rod 26 or the flip-chip connecting rod 34. The Micro-LED 11 on the substrate 12 can be flexibly transferred to the target board 13. Entirely controllable mass transfer of electronic component distance can be achieved.

The operation platform includes a visualized PLC screen and an integrated PLC control system, and the integrated PLC control system is electrically connected to the die-bond linear motor 27, the die-bond driving movement platform, the flip-chip rotating motor 31, the flip-chip linear motor and the flip-chip driving movement platform 37, respectively.

The setting of the PLC screen on the operation platform can perform a visualization operation, so as to conveniently view various parameters and set various parameters, and the parameters of the PLC program can also be modified without a computer, and the use is more convenient.

The die-bond welding arm further includes a die-bond limiting device 21, and the die-bond limiting device 21 is disposed at one end of the die-bond rail 23 for limiting the die-bond brackets 24 on the die-bond rail 23.

The flip-chip welding arm further includes a flip-chip limiting device 32, and the flip-chip limiting device 32 is arranged at one end of the flip-chip rail 33 for limiting the flip-chip brackets 35 on the flip-chip rail 33.

When the plurality of die-bond brackets 24 slide on the die-bond rail 23, the die-bond brackets 24 at the ends can easily slide out of the die-bond rail 23 to cause damage, and the die-bond limiting device 21 can limit the sliding range of the die-bond brackets 24 within the die-bond rail 23 to prevent the die-bond brackets 24 from sliding out of the die-bond rail 23 to be damaged. Likewise, the flip-chip limiting device 32 can also protect the flip-chip brackets 35 and prevent the flip-chip brackets 35 from sliding out of the flip-chip rail 33 to be damaged.

A transferring method using the variable pitch electronic component mass transfer apparatus includes the following steps:

Step 1: driving the Z axis of the flip-chip driving movement platform, so that the flip-chip transfer head 36 is kept at a distance from the Micro-LED 11, and then driving the XY axis of flip-chip driving movement platform to perform machine vision alignment;

Step 2: driving the flip-chip linear motor 37 according to the pitch of the substrate Micro-LED 11 to be grabbed, changing the length of the flip-chip connecting rod 34, so that each flip-chip transfer head 36 is aligned with the Micro-LED 11 of the substrate 12 respectively;

Step 3: applying a positive voltage to all the flip-chip transfer heads 36 to grasp the Micro-LED 11 of the substrate 12;

Step 4: driving the flip-chip rotating motor 31 so that the flip-chip welding arm is inverted 180 degrees, and then driving the XY axis of the die-bond driving movement platform and the die-bond linear motor 27 so that the die-bond transfer head 25 aligns the Micro-LED 11 on the flip-chip transfer head 36, and then driving the Z axis of the die-bond driving platform so as to press the die-bond transfer head 25 on the Micro-LED; then applying a positive voltage to the die-bond transfer head 25 to grasp the Micro-LED 11, and applying a negative voltage to the flip-chip transfer head 36 to release the Micro-LED 11;

Step 5: driving the die-bond linear motor 27 according to the distance required when the micro-LED 11 is placed wherein the distance between two adjacent die-bond brackets 24 is c 1, then changing the length of the die-bond connecting rod 26 wherein the distance between two adjacent die-bond brackets 24 is c2 and the distance between two adjacent die-bond transfer heads 25 is L2;

Step 6: driving the XY axis of the die-bond driving movement platform, positioning the Micro-LED 11 grasped by the die-bond transfer head 25 at a target position, then driving the Z axis of the die-bond driving movement platform, moving the die-bond transfer head 25 down to a target board, and then applying a negative voltage to the die-bond transfer head 25, so that the die-bond transfer head 25 releases the Micro-LED;

Step 7: returning to Step 1.

In the existing transfer method, the transfer heads in the transfer mechanism are generally connected by a rigid structure, so that the distance between the transfer heads cannot be adjusted after the transfer heads grab the Micro-LED 11 from the substrate 12, so that the distance of the transfer heads placing on the target substrate 13 cannot be controlled, so that the distance between the Micro-LED 11 in the target board 13 can only depend on the transfer head template distance. In the present disclosure, two adjacent die-bond brackets 24 and flip-chip brackets 35 are connected by using a die-bond connecting rod 26 and a flip-chip connecting rod 34. The distance between two adjacent die-bond brackets 24 can be changed by changing the length of the die-bond connecting rod 26. Thus, the Micro-LED 11 is precisely grabbed. The length of the flip-chip connecting rod 34 is changed according to the pitch of the Micro-LED 11 to be placed, so as to change the distance between two adjacent coating brackets 35. In this way, the Micro-LED 11 is precisely placed on the target board 13. Thus, the distance between the electronic components is completely controllable, which inventively overcomes the limitation that the Micro-LED 11 spacing of the target board 13 can only depend on the transfer head template distance. The present disclosure has great application value in the field of semiconductor manufacturing and has higher social economy benefits.

A longitudinal linear deformation coefficient of the die-bond connecting rod 26 is c, and in the step 5, after the die-bond linear motor 27 is driven to change the length of the die-bond connecting rod 26, the pitch between two adjacent die-bond transfer heads 25 is c2=c1*c.

The pitch of the Micro-LEDs 11 of the substrate 12 is L1, a grabbing point is marked every a elements, and the pitch of two adjacent Micro-LEDs on the target board 13 is L2, that is, L2=L1*a*c.

Since the distance between adjacent Micro-LEDs 11 is small, the die-bond welding arms can grasp every a components when grabbing the Micro-LEDs 11 on the substrate 12, so when the die-bond welding arms place the Micro-LEDs 11, the die-bond welding arms need to be separated by a certain distance, that is, L2=L1*a*c.

A response time of the die-bond connecting rod 26 and the flip-chip connecting rod 34 is 10-100 ms.

When the response time of the die-bond connecting rod 26 and the flip-chip connecting rod 34 is less than 10 ms, since the speed of is fast, an impact is easily generated, so that the Micro-LED 11 grasped by the die-bond transfer head 25 or the flip-chip transfer head 36 is easily dropped, thereby affecting the yield. When the response time of the die-bond connecting rod 26 and the flip-chip connecting rod 34 is greater than 100 ms, since the response time is long, the transfer speed is slow and the production efficiency is slow.

The technical principles of the present disclosure are described above in connection with specific embodiments. These descriptions are merely intended to explain the principles of the present disclosure and not to be construed in any way as limiting the scope of protection of the present disclosure. Based on the explanation herein, the skilled in the art would have been able to conceive other specific embodiments of the present disclosure without involving any inventive effort, which all belong to the scope of protection of the present disclosure.

What is claimed is:

1. A variable pitch electronic component mass transfer apparatus, comprising a die-bond welding arm, a die-bond driving movement platform, a flip-chip welding arm, a flip-chip driving movement platform and an operation platform; wherein a plurality of die-bond welding arms are provided, and each of the die-bond welding arms comprises a die-bond rail, a die-bond bracket, a die-bond transfer head, a die-bond connecting rod and a die-bond linear motor; a plurality of die-bond brackets are provided, and the plurality of die-bond brackets are all slidably connected to the die-bond rail; a plurality of die-bond transfer heads are disposed below each of the die-bond brackets; the die-bond connecting rod is provided with die-bond movable nodes arranged equidistantly; each of the die-bond movable node is hinged to one of the die-bond brackets; the die-bond linear motor is disposed at one end of the die-bond rail; an output end of the die-bond linear motor drives the die-bond connecting rod to move telescopically; the die-bond welding arm is connected to the die-bond driving movement platform, and the die-bond driving movement platform drives the die-bond welding arm to move along X, Y and Z axes; a number of the flip-chip welding arms is the same as a number of the die-bond welding arms; each of the flip-chip arms comprises a flip-chip rotating motor, a flip-chip rail, a flip-chip bracket, a flip-chip transfer head, a flip-chip connecting rod and a flip-chip linear motor; a plurality of flip-chip brackets are provided, and the plurality of flip-chip brackets are all slidably connected to the flip-chip rail; a flip-chip transfer head is disposed below each of the flip-chip brackets; the flip-chip connecting rod is provided with flip-chip movable nodes arranged equidistantly; each of the flip-chip movable nodes is hinged to one of the flip-chip brackets; the flip-chip linear motor is disposed at one end of the flip-chip rail; an output end of the flip-chip linear motor drives the flip-chip connecting rod to move telescopically; an output end of the connecting rod rotating motor is connected to the flip-chip rail, and is configured to turn over the flip-chip rail; the flip-chip welding arm is connected to the flip-chip driving movement platform, the flip-chip driving movement platform drives the flip-chip welding arm to move along X, Y and Z axes, and the flip-chip driving movement platform is provided with a visual servo alignment system; and the die-bond linear motor, the die-bond driving platform, the flip-chip rotating motor, the flip-chip linear motor and the flip-chip driving platform are electrically connected to the operation platform.

2. The variable pitch electronic component mass transfer apparatus of claim 1, wherein the die-bond transfer heads and the flip-chip transfer heads are both bipolar transfer heads, a Micro-LED is grasped when a positive voltage is applied, and a Micro-LED is released when a negative voltage is applied; the die-bond connecting rod and the flip-chip connecting rod are both parallelogram mechanisms; the parallelogram mechanism comprises a plurality of first links and a plurality of second links; the length of the first link is the same as the length of the second link; the midpoint of each of the first links and the midpoint of one of the second links are hinged to each other, forming an X-shaped module; two adjacent X-shaped modules being hinged to each other to form the parallelogram mechanism; the two adjacent X-shaped module hinges are the active nodes; two ends of the parallelogram mechanism are further provided with a third link and a fourth link, one end of the third link is hinged to an end of a first link located at one end of the parallelogram, and the other end of the third link is the movable node; one end of the fourth link is hinged to an end of a second link located at the other end of the parallelogram, and the other end of the fourth link is the movable node.

3. The variable pitch electronic component mass transfer apparatus of claim 1, wherein the operation platform comprises a visualized PLC screen and an integrated PLC control system, and the integrated PLC control system is electrically connected to the die-bond linear motor, the die-bond driving movement platform, the flip-chip rotating motor, the flip-chip linear motor and the flip-chip driving movement platform, respectively.

4. The variable pitch electronic component mass transfer apparatus of claim 1, wherein the die-bond welding arm further comprises a die-bond limiting device, and the die-bond limiting device is disposed at one end of the die-bond rail for limiting the die-bond brackets on the die-bond rail; the flip-chip welding arm further comprises a flip-chip limiting device, and the flip-chip limiting device is arranged at one end of the flip-chip rail for limiting the flip-chip brackets on the flip-chip rail.

5. A transferring method using the variable pitch electronic component mass transfer apparatus of claim 1, comprising the following steps:
Step 1: driving the Z axis of the flip-chip driving movement platform, so that the flip-chip transfer head is kept at a distance from the Micro-LED, and then driving the XY axis of flip-chip driving movement platform to perform machine vision alignment;
Step 2: driving the flip-chip linear motor according to the pitch of the substrate Micro-LED to be grabbed, changing the length of the flip-chip connecting rod, so that each flip-chip transfer head is aligned with the Micro-LED of the substrate respectively;
Step 3: applying a positive voltage to all the flip-chip transfer heads to grasp the Micro-LED of the substrate;
Step 4: driving the flip-chip rotating motor so that the flip-chip welding arm is inverted 180 degrees, and then driving the XY axis of the die-bond driving movement platform and the die-bond linear motor so that the die-bond transfer head aligns the Micro-LED on the flip-chip transfer head, and then driving the Z axis of the die-bond driving platform so as to press the die-bond transfer head on the Micro-LED; then applying a positive voltage to the die-bond transfer head to grasp the Micro-LED, and applying a negative voltage to the flip-chip transfer head to release the Micro-LED;
Step 5: driving the die-bond linear motor according to the distance required when the micro-LED is placed wherein the distance between two adjacent die-bond brackets is c1, then changing the length of the die-bond connecting rod wherein the distance between two adjacent die-bond brackets is c2 and the distance between two adjacent die-bond transfer heads is L2;
Step 6: driving the XY axis of the die-bond driving movement platform, positioning the Micro-LED grasped by the die-bond transfer head at a target position, then driving the Z axis of the die-bond driving movement platform, moving the die-bond transfer head down to a target board, and then applying a negative voltage to the die-bond transfer head, so that the die-bond transfer head releases the Micro-LED;
Step 7: returning to Step 1.

6. The transferring method using the variable pitch electronic component mass transfer apparatus of claim 5, wherein a longitudinal linear deformation coefficient of the die-bond connecting rod is c, and in the step 5, after the die-bond linear motor is driven to change the length of the die-bond connecting rod, the pitch between two adjacent die-bond transfer heads is c2=c1*c.

7. The transferring method using the variable pitch electronic component mass transfer apparatus of claim 6, wherein the pitch of the Micro-LEDs of the substrate is L1, a grabbing point is marked every a elements, and the pitch of two adjacent Micro-LEDs on the target board is L2, that is, L2=L1*a*c.

8. The transferring method using the variable pitch electronic component mass transfer apparatus of claim 5, wherein a response time of the die-bond connecting rod and the flip-chip connecting rod is 10-100 ms.
